(19) United States
(12) Patent Application Publication
(10) Pub. No.: US 2005/0209918 A1
(43) Pub. Date: Sep. 22, 2005

(54) Listening supplement that provides an additional or alternative means of media content delivery of periodical publications for subscribers of the aforementioned periodical publications and a process for establishing the same

(76) Inventor: Stanley Mitchell Ferrell, Roswell, GA (US)

Correspondence Address: IN-LINE GRAPHICS SOLUTIONS, INC., P.O. BOX 18081, ATLANTA, GA, 30316, US

(21) Appl. No.: 10/805,793

(22) Filed: Mar. 22, 2004

(51) Int. Cl. G06F 17/60; H03G 3/00

(52) U.S. Cl. 705/14

(57) ABSTRACT

The current invention is a listening supplement that provides an additional or alternative of news delivery for readers of periodical publications and a process for establishing the same. The listening supplement is contained as a bound insert to a periodical. The listening supplement has highlights or “cover stories” read by an editor or author of the story (Newscaster, Public Relations professional, Public Radio announcers, etc.). The listening supplement contains any subject matter chosen periodical publication. Furthermore, the listening supplement provides a medium for advertisers to reach their target audience. The listening supplement is stored in a bi-folded carrier device with a clear plastic front and an envelope flap on back. The carrier consists of a single sheet of paperboard folded along a bi-fold line with an envelope flap on the back of one side of the bi-fold (See FIG. 4) and a paperboard on the other side (See FIG. 2).

### CROSS REFERENCE TO RELATED APPLICATIONS

Not Applicable

### STATEMENT REGARDING FEDERALLY SPONSORED RESEARCH OR DEVELOPMENT

Not Applicable

### DESCRIPTION OF ATTACHED APPENDIX

Not Applicable

### BACKGROUND OF THE INVENTION

This invention relates generally to the field of communications and advertising and more specifically to a listening supplement that provides an additional or alternative means of media content delivery of periodical publications for subscribers of the aforementioned periodical publications and a process for establishing the same.

Many publications have become huge outlets for promoting goods and services and for delivering news. Their reach is worldwide. Likewise, CDs and DVDs are used virtually everywhere today. They are used to hold music, data or computer software. As a result, they have become the standard medium for distributing large quantities of information in a reliable and structurally sound package. Compact discs are easy and cost-effective to produce. A DVD is very similar to a CD, but it has a much larger data capacity. A standard DVD holds approximately seven times more data than a CD does. These technologies have been used in tandem with one another in the delivery of software and other promotional items for on-line providers and for other merchants.

Earlier patents have been geared towards securing a carrier device for CDs or other storage media into books. For example, U.S. Pat. No. 6,446,417 B1, discusses an article-embedded folding sleeve and a method for producing the same. Furthermore, U.S. Pat. No. 6,016,907, describes a cover or insert for a periodical. Likewise, U.S. Pat. No. 6,068,117, addresses the use of a book insert CD carrier device. These inventions attempt to meet the challenges of securely binding storage media to their attached periodicals. These inventions differ in many ways from the current invention. In this invention, the storage media serves as a vehicle for the delivery of information of the periodical to which is attached. The particular binding of that media is less important than the actual purpose of that storage media. The storage media of the previous inventions (i.e., listening supplement) has yet to offer an alternative or additional means of reaching periodical subscribers through the use of a listening supplement. The current invention clearly achieves that objective.

For many centuries, periodicals have been a medium for reaching an audience of mass consumers. They have long been produced by new and faster printing processes, and they were supported by advertising. More recently, many periodicals have engaged in on-line subscriptions in an attempt to reach a larger audience. This was done largely in part to bring the news to the subscriber in a more convenient manner. This has resulted in only a modest increase in subscriptions.

According to a Special Report of Magazine Circulation by Ad Age (Mar. 15, 2004), 70% of publications are suffering from declining newsstand sales. The report states that different strategies have been attempted, and publishers are continuously searching for ways to rectify the current situation. Furthermore, the article indicates that the stakes go beyond lost circulation revenue, to marketers skeptical about magazines' value as an ad medium desired by consumers. Current evidence suggests that the current circulation model is broken for both publishers and advertisers. Circulators today view web-generated subscriptions as a solid part of the subscription mix, but a far from being the dominant player.

Prior technology does not the address the ways and means that magazine readers can better access the content that they need. Over the last decade, there has been an increasing integration of work-life relationships. As a result, periodical publications must be able to address such issues. The current invention contained herein adequately achieves those objectives. The invention provides a listening supplement for readers of scheduled periodicals. The subscriber can use the listening supplement in conjunction with the physically-printed periodical publication or the on-line publication or as a stand-alone item. The listening supplement contains any media content coverage chosen by the publication or its designee. Each piece of media content is contained on separate data storage areas (e.g., tracks or chapters) and the listener is able to reach each piece of media content in discrete steps. Each listening supplement has its respective table of contents to guide the reader through the contents of the listening supplement as designated by the publication.

The listening supplement provides an innovative process of hearing news and media content for subscribers of regular periodicals. As a result, the subscriber gains more value for the dollar invested in annual subscriptions. Also, the listening supplement provides more time and more convenience for the time-conscious individual by effectively creating “up time.” Another huge benefit is that the listening supplement provides media coverage for subscribers who are visually challenged or impaired.

The listening supplement through use of a carrier device is sewn into the sleeve either through a manual or automated process. The listening supplement is contained in a carrier device that allows for the packaging of the listening supplement with the periodical as one unit that is both cost-effective and lightweight. This configuration does not add bulk nor does it increase the dimensional size of the book. The carrier device serves as a holder for a listening supplement when the listening supplement is not being used.

### BRIEF SUMMARY OF THE INVENTION

The primary object of the invention is to be able to provide a listening supplement for readers of regular periodical publications (monthly, weekly, etc.).

Another object of the invention is to increase the subscriber base of major periodicals throughout alternative outreach.

A further object of the invention is to provide an alternative outreach medium in a cost-effective manner.

Another object of the invention is to provide an another outlet for advertisers to reach their target audience.

Yet another object of the invention is to gain more value for the dollar invested in annual subscriptions.

Still yet another object of the invention is to better help visually challenged or impaired individuals able to hear the highlights of the magazine.

A further object of the invention is to provide more time and more convenience for time-conscious individual.

Other objects and advantages of the present invention will become apparent from the following descriptions, taken in connection with the accompanying drawings, wherein, by way of illustration and example, an embodiment of the present invention is disclosed.

In accordance with a preferred embodiment of the invention, there is disclosed a listening supplement that provides an additional or alternative means of news delivery for readers of a periodical publication and a process for establishing the same comprising: a listening supplement contained as an insert to a periodical, a listening supplement having highlights or “cover stories” read by an editor or author of the story (Newscaster, Public Relations professional, Public Radio announcers, etc.), a listening supplement containing any type of coverage that the management team of the periodical publication want to include, a listening supplement providing a medium by which advertisers of periodicals reach their target audience, a listening supplement storied in a bi-folded carrier device with a clear plastic front and an envelope flap on back, and A carrier is a single sheet of paperboard folded along a bi-fold line with an envelope flap on the back of one side of the bi-fold (See FIG. 4).

### BRIEF DESCRIPTION OF THE DRAWINGS

The drawings constitute a part of this specification and include exemplary embodiments to the invention, which may be embodied in various forms. It is to be understood that in some instances various aspects of the invention may be shown exaggerated or enlarged to facilitate an understanding of the invention.

FIG. 1 is a perspective view of the invention with a periodical publication as shown with the window on the frontal view showing the packaged supplement and information printed onto the listening supplement.

FIG. 2 is a perspective view of the invention showing its position within its carrier.

FIG. 3 is a perspective view of the invention and its carrier and their position within the periodical publication.

FIG. 4 is a plan view of the invention showing both the front and rear view of its secured pocket with an envelope flap on the back side. It also shows the paperboard carrier and its position in relation to the invention.

### DETAILED DESCRIPTION OF THE PREFERRED EMBODIMENTS

Detailed descriptions of the preferred embodiment are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

In accordance with the present invention, FIG. 1.11 represents the periodical publication. FIG. 1.10 represents the title and cover stories of the designated periodical. A periodical includes any magazine, journal, or the like printed or on-line item. A subscriber of such periodical includes a printed subscriber or an on-line subscriber. Turning first to FIG. 1.12, the invention covers the “highlights” or “cover stories” read by an editor or author of the story (Newscaster, Public Relations professional, Public Radio announcers, etc.) The term “highlights” or “cover stories” refers to any type of article publication content contained within the periodical as designated by the said periodical. The term “listening supplement” is used to describe any CD, DVD, or any storage type media.

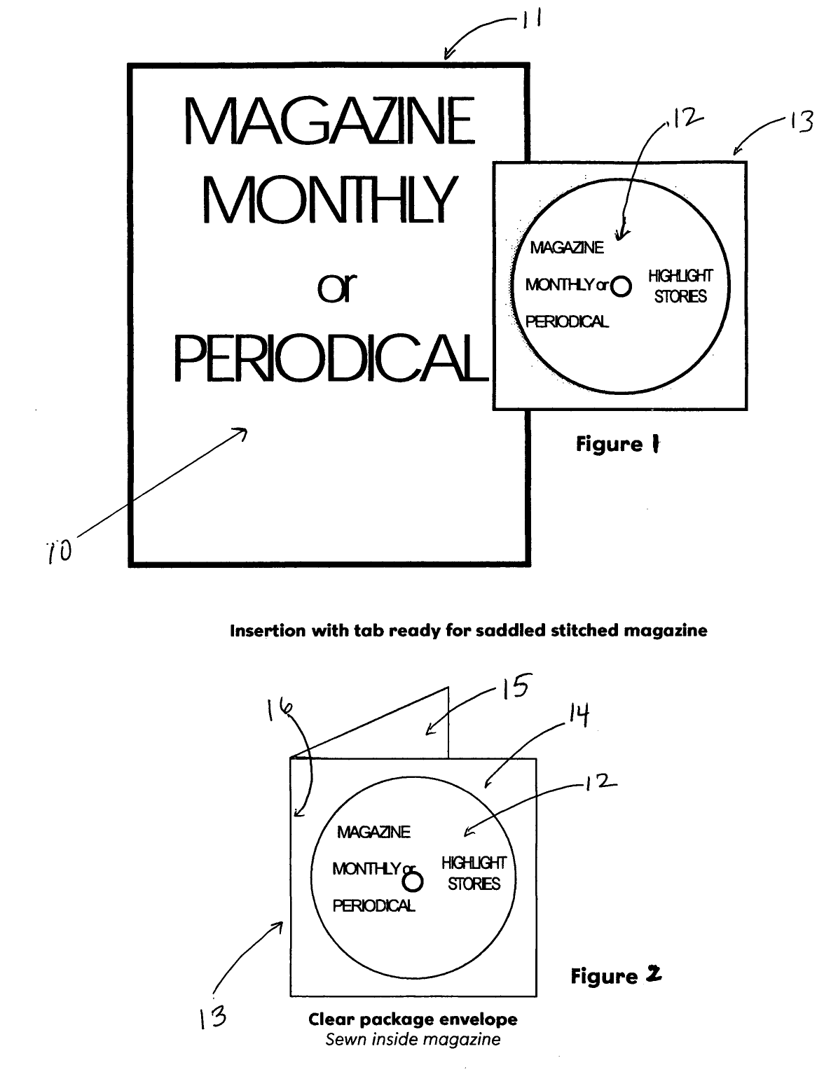

To accomplish an important function of the invention, there is shown in FIG. 1.12, a clear window that allows a view of the packaged article and any information printed on the listening supplement. Each listening supplement has its respective table of contents to guide the reader through the contents of the listening supplement as designated by the publication as designated in FIG. 2.12. Each piece of media content is contained on separate data storage areas (e.g., tracks or chapters) and the listener is able to reach each piece of media content in discrete steps.

Currently, there are several types of apparatus that allows for the packaging of a listening supplement with a book. The purpose of this invention is not to capture a unique embodiment. Rather, the current invention is more focused on creating an innovative process of hearing news content for subscribers of regular periodicals through the use of an inserted or bound listening supplement, with less emphasis on the preferred configuration for establishing such packaging. Yet, another purpose is to provide a listening supplement for readers of regular periodical publications (monthly, weekly, etc.). As a result of this invention, subscribers are able to receive much of their publication content through an alternative medium. Furthermore, advertisers are better able to reach, and therefore serve, their target audience.

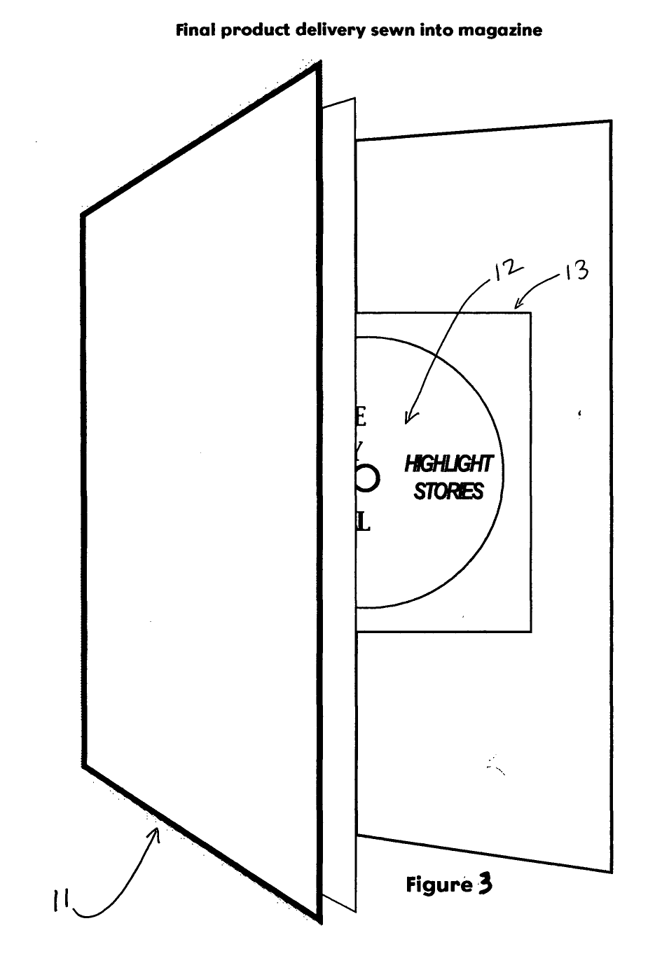

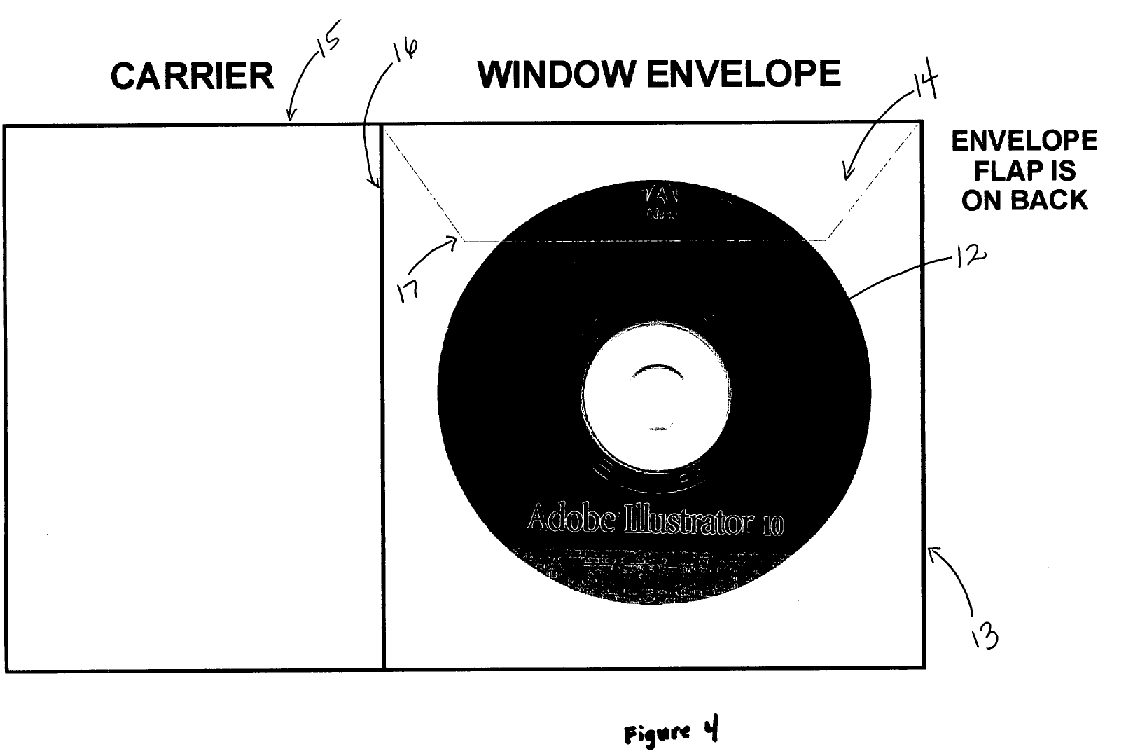

The preferred embodiment of the listening supplement is dependent upon the optimal configuration of the publication based on newsstand configurations and best practices. The publishing industry prefers a listening supplement that permits the packaging of the aforementioned article as a single unit with the designated periodical (See FIGS. 3.12 and 3.13). The preference is for the attached article to be sewn inside the magazine so that the periodical and the listening supplement are contained as one unit (See FIGS. 2.13 and 3.12). This allows for the listening supplement to be inserted into the periodical securely in a non-loosely, theft-proof manner. This allows the periodical to remain lightweight and free of bulidness. Furthermore, as shown in FIG. 4.15, the CD is able to be stored in a storage unit or carrier within the periodical while not in use. A carrier is a single sheet of paperboard folded along a bi-fold line with an envelope flap on the back of one side of the bi-fold (See FIG. 4). As shown in FIG. 2, the listening supplement is stored in a bi-folded carrier device with a clear plastic front (See FIG. 2.14) and an envelope flap (See FIG. 4.17) on back; and the said carrier is detachably bound to the publication (See FIG. 3.13). A carrier device allows for optimal packaging of the listening supplement so that it is sewn to the inside of the magazine along the bi-fold (FIG. 2.16). The carrier device has the periodical as its carrier device (See FIG. 3.13).

While the invention has been described in connection with a preferred embodiment, it is not intended to limit the scope of the invention to the particular form set forth, but on the contrary, it is intended to cover such alternatives, modifications, and equivalents as may be included within the spirit and scope of the invention as defined by the appended claims.

1. A listening supplement that provides an additional or alternative means of media content delivery of periodical publications for subscribers of the aforementioned periodical publications and a process for establishing the same comprising:
a listening supplement contained as an insert to a periodical;
a listening supplement having highlights or “cover stories” read by an editor or author of the story (Newscaster, Public Relations professional, Public Radio announcers, etc.);
a listening supplement containing any type of coverage that the said periodical publication designates;
a listening supplement containing a table of contents with each separate piece of media content on separate data storage areas (e.g., tracks, chapters);
a listening supplement wherein the listener is able to reach each piece of media content in discrete steps.
a listening supplement providing a medium by which advertisers of periodicals reach their target audience through the use of data storage space;
a listening supplement stored in a bi-folded carrier device with a clear plastic front and an envelope flap on back; and
a carrier with a single sheet of paperboard folded along a bi-fold line with an envelope flap on the back of one side of the bi-fold (See FIG. 4).
